(19) United States
(12) Patent Application Publication
(10) Pub. No.: US 2002/0084825 A1
(43) Pub. Date: Jul. 4, 2002

(54) Small swing output buffer for reducing EMI

(76) Inventors: Yi-Ren Hwang, Tainan (TW); Jeng-Huang Wu, Taipei (TW)

Correspondence Address: J.C. Patents, Inc., 4 Venture, Suite 250, Irvine, CA, 92618, US

(21) Appl. No.: 09/754,455

(22) Filed: Jan. 4, 2001

(51) Int. Cl. H03K 17/16; H03K 19/003; H03K 19/00; H03K 5/08; H03K 3/00; H03L 5/00

(52) U.S. Cl. 327/328; 326/102; 326/23; 327/327; 327/306; 327/309; 327/318

(57) ABSTRACT

The small swing output buffer of the present invention comprises, for example, four transistors or FETs; P1, P2, N1, and N2. The source of P2 is connected to Vcc and the drain of P2 is connected to the source of P1. The drain of PI is connected to the source of N1. The drain of N1 is connected to the source of N2. The drain of N2 is connected to ground. The input signal to the output buffer is fed into input IN which is connected to the gates of P1 and N1. The output of the output buffer is output OUT which is connected to the drain of P1 and the source of N1. For the small swing output buffer, when the input signal is at a high potential, P1 and P2 are turned off and N1 and N2 are turned on which pulls down the potential of OUT towards ground potential. Since FETs have a threshold voltage, the potential of the output OUT cannot be completely pulled to ground potential. Therefore, the potential of the output OUT when the input signal applied to IN is a high potential, is the threshold voltage (Vt) of N2. When the input signal applied to IN is at a low potential, P1 and P2 are turned on and N1 and N2 are turned off which pulls up the potential of OUT towards Vcc. Therefore, the potential of the output OUT when the input signal applied to IN is a low potential, is Vcc minus the threshold voltage (Vt) of P2. The diode structure of the P1 and N1 devices automatically and simply cut Vt out of the power supply voltage and the ground respectively. As a result of the decreased swing of the output buffer, EMI problems can be significantly reduced. Additionally, since the output swing of the small swing output buffer of the present invention is smaller, the output buffer has less delay time and lower noise.

### BACKGROUND OF THE INVENTION

1. Field of Invention

The present invention relates to an output buffer, and more particularly to a small swing output buffer that reduces EMI.

2. Description of Related Art

Electromagnetic Interference (EMI) is an increasing problem for electronic products. Adverse effects to the human body are one concern. Another problem caused by EMI is malfunction or improper operation of precision equipment and apparatus. A significant contributor for EMI is the large swing of output buffers in electronic circuitry.

FIG. 1 shows a circuit diagram of a conventional output buffer. In the conventional output buffer, an input signal is fed into the output buffer via the input IN 10. The conventional output buffer is made up of two transistors or FETs; P1 20 and N1 30. The source of P1 20 is connected to Vcc and the drain of P1 20 is connected to the source of N1 30. The drain of N1 30 is connected to ground. The gates of both P1 20 and N1 30 are connected to the input IN 10. The output of the output buffer is the output OUT 40, which is connected to the drain of P1 20 and the source of N1 30.

Since the input signal applied to input IN 10 is generally one of two logic levels, a high potential or a low potential, the output OUT 40 is dependent on the input IN 10 and will adjust potential accordingly.

For the conventional output buffer shown in FIG. 1, when the input signal is at a high potential, P1 20 is turned off and N1 30 is turned on which pulls down the potential of OUT 40 to ground potential. When the input signal is at a low potential, P1 20 is turned on and N1 30 is turned off which pulls up the potential of OUT 40 to Vcc.

In other words, if IN 10 is a logic low level, OUT 40 equals Vcc. If IN 10 is a logic high level, OUT 40 equals ground or 0 volts. Therefore the swing of the conventional output buffer shown in FIG. 1 is from 0 volts to Vcc. Any changes or variations in the input signal applied to IN 10 are quickly apparent in the output signal at OUT 40.

As the operating speed or frequency of electronic circuitry increases, the devices in the output buffer must turn on and off more rapidly. Since the swing of the output buffer is relatively large, as in from Vcc to ground, the switching or swinging back and forth of the output of the output buffer significantly increases the problems associated with EMI.

### SUMMARY OF THE INVENTION

In order to overcome the shortcomings and disadvantages of the conventional design, the invention provides a small swing output buffer, which reduces EMI problems.

Due to the fact that a major contributor to the EMI problem is from the large swing of the output buffer by simply reducing the swing of an output buffer, EMI problems are significantly reduced.

The small swing output buffer of the present invention comprises, for example, four transistors or FETs; P1, P2, N1, and N2. The source of P2 is connected to Vcc and the drain of P2 is connected to the source of P1. The drain of P1 is connected to the source of N1. The drain of N1 is connected to the source of N2. The drain of N2 is connected to ground. The input signal to the output buffer is fed into input IN which is connected to the gates of P1 and N1. The output of the output buffer is output OUT which is connected to the drain of P1 and the source of N1.

Since the input signal applied to input IN is generally one of two logic levels, a high potential or a low potential, the output OUT is dependent on the input IN and will adjust potential accordingly.

For the small swing output buffer, when the input signal is at a high potential, P1 and P2 are turned off and N1 and N2 are turned on which pulls down the potential of OUT towards ground potential. However, when the input signal applied to IN is a high potential, FETs N1 and N2 begin conducting. Since FETs have a threshold voltage, the potential of the output OUT cannot be completely pulled to ground potential. Therefore, the potential of the output OUT when the input signal applied to IN is a high potential, is the threshold voltage (Vt) of N2.

When the input signal applied to IN is at a low potential, P1 and P2 are turned on and N1 and N2 are turned off which pulls up the potential of OUT towards Vcc. However, a similar situation as previously explained occurs. When the input signal applied to IN is a low potential, FETs P1 and P2 begin conducting. Since FETs have a threshold voltage, the potential of the output OUT cannot be completely pulled up to Vcc. Therefore, the potential of the output OUT when the input signal applied to IN is a low potential, is Vcc minus the threshold voltage (Vt) of P2.

In other words, if IN is a logic low level, OUT equals Vcc−Vt. If IN is a logic high level, OUT equals ground+Vt. Therefore the swing of the small swing output buffer of an embodiment of the present invention is from Vt to Vcc−Vt for a voltage swing of Vcc−2Vt.

The diode structure of the P1 and N1 devices automatically and simply cut Vt out of the power supply voltage and the ground respectively.

As a result of the decreased swing of the output buffer, EMI problems can be significantly reduced. Additionally, since the output swing of the small swing output buffer of the present invention is smaller, the output buffer has less delay time and lower noise.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 shows a schematic diagram of a conventional output buffer;

FIG. 2 shows a small swing output buffer of an embodiment of the present invention; and

FIG. 3 shows a small swing output buffer of an embodiment of the present invention.

### DESCRIPTION OF THE PREFERRED EMBODIMENTS

In order to overcome the shortcomings and disadvantages of the conventional design, the invention provides a small swing output buffer, which reduces EMI problems.

Due to the fact that a major contributor to the EMI problem is from the large swing of the output buffer by simply reducing the swing of an output buffer, EMI problems are significantly reduced.

Refer to FIG. 2, which shows a circuit diagram for a small swing output buffer of an embodiment of the present invention.

The small swing output buffer of FIG. 2 comprises four transistors or FETs; P1 120, P2 150, N1 130, and N2 160. The source of P2 150 is connected to Vcc and the drain of P2 150 is connected to the source of P1 120. The drain of P1 120 is connected to the source of N1 130. The drain of N1 130 is connected to the source of N2 160. The drain of N2 160 is connected to ground. The input signal to the output buffer is fed into input IN 100 which is connected to the gates of P1 120 and N1 130. The output of the output buffer is output OUT 140 which is connected to the drain of P1 120 and the source of N1 130.

Since the input signal applied to input IN 100 is generally one of two logic levels, a high potential or a low potential, the output OUT 140 is dependent on the input IN 100 and will adjust potential accordingly.

For the small swing output buffer shown in FIG. 2, when the input signal is at a high potential, P1 120 and P2 150 are turned off and N1 130 and N2 160 are turned on which pulls down the potential of OUT 140 towards ground potential. However, when the input signal applied to IN 100 is a high potential, FETs N1 130 and N2 160 begin conducting. Since FETs have a threshold voltage, the potential of the output OUT 140 cannot be completely pulled to ground potential. Therefore, the potential of the output OUT 140 when the input signal applied to IN 100 is a high potential, is the threshold voltage (Vt) of N2 160.

When the input signal applied to IN 100 is at a low potential, P1 120 and P2 150 are turned on and N1 130 and N2 160 are turned off which pulls up the potential of OUT 140 towards Vcc. However, a similar situation as previously explained occurs. When the input signal applied to IN 100 is a low potential, FETs P1 120 and P2 150 begin conducting. Since FETs have a threshold voltage, the potential of the output OUT 140 cannot be completely pulled up to Vcc. Therefore, the potential of the output OUT 140 when the input signal applied to IN 100 is a low potential, is Vcc minus the threshold voltage (Vt) of P2 150.

In other words, if IN 100 is a logic low level, OUT 140 equals Vcc−Vt. If IN 100 is a logic high level, OUT 140 equals ground+Vt. Therefore the swing of the small swing output buffer shown in FIG. 2 of an embodiment of the present invention is from Vt to Vcc−Vt for a total voltage swing of Vcc−2Vt.

The diode structure of the P1 and N1 devices automatically and simply cut Vt out of the power supply voltage and the ground respectively.

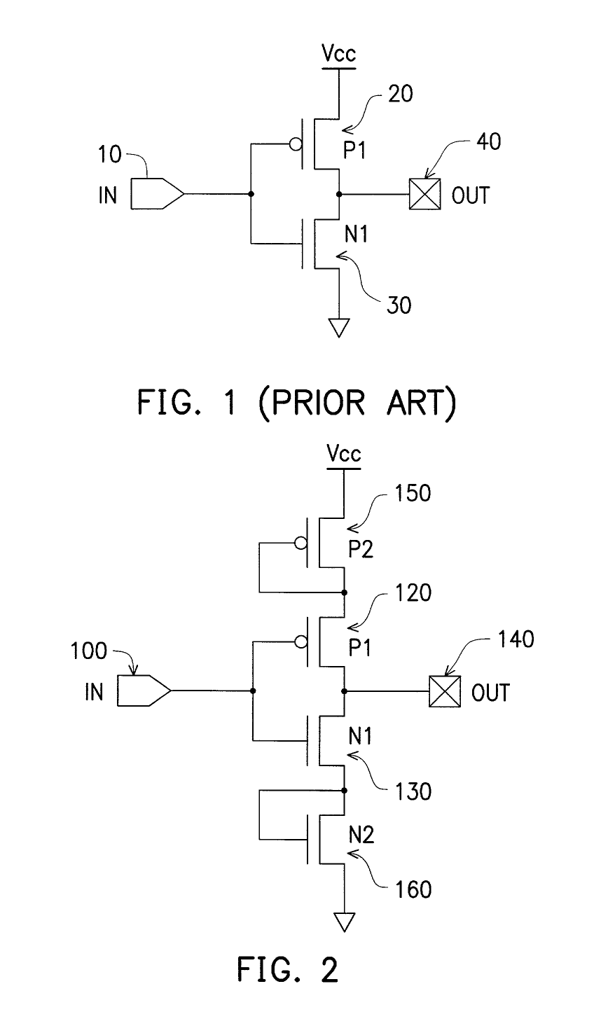

Referring back to FIG. 1, in the conventional output buffer the output swing is from 0 volts to Vcc for a total swing of Vcc. However, with the circuit of FIG. 2, the output swing is reduced to from Vt to Vcc−Vt for a total swing of Vcc−2Vt due to the clamping effect of the P1 and N1 devices.

As a result of the decreased swing of the output buffer, EMI problems can be significantly reduced. Additionally, since the output swing of the small swing output buffer of the present invention is smaller, the output buffer has less delay time and lower noise.

It should be noted that the small swing output buffer of the present invention is not limited to the above configuration. Additional FETs or devices can be added to the circuit of FIG. 2 to further limit the swing of the output buffer.

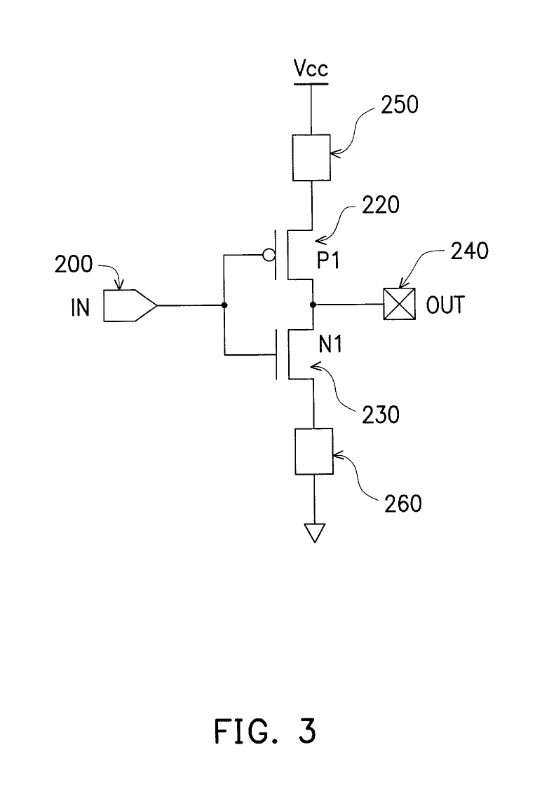

Refer to FIG. 3, which shows a block diagram of an embodiment of the present invention. The threshold voltage drop elements 250 and 260 can contain a plurality of devices that operate in such a manner as to limit the resultant output swing of the output buffer.

For example, threshold voltage drop elements 250 and 260 could both contain two or more FETs. This would result in the output swing of the output buffer at OUT 240 being from 2Vt to Vcc−2Vt or 3Vt to Vcc−3Vt.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A small swing output buffer comprising:
a first p-channel FET with a source, gate, and drain;
a second p-channel FET with a source, gate, and drain;
a first n-channel FET with a source, gate, and drain; and
a second n-channel FET with a source, gate, and drain;
wherein the source of the first p-channel FET is connected to Vcc and the gate and drain are connected to the source of the second p-channel FET, the drain of the second p-channel FET is connected to the source of the first n-channel FET, the drain of the first n-channel FET is connected to the source and gate of the second n-channel FET, the drain of the second n-channel FET is connected to ground, the gate of the second p-channel FET is connected to the gate of the first n-channel FET and both gates are connected to an input, and the drain of the second p-channel connector and the source of the first n-channel FET are connected together and connect to an output of the small swing output buffer.

2. The small swing output buffer of claim 1, wherein a plurality of duplicate first p-channel FETs are connected between the source of the first p-channel FET and Vcc and a plurality of duplicate second n-channel FETs are connected between the drain of the second n-channel FET and ground.

3. A small swing output buffer comprising:
means for limiting the swing of an output buffer in order to reduce EMI.

4. A small swing output buffer comprising:
a plurality of pull-up transistors connected to a voltage supply; and
a plurality of pull-down transistors connected to ground, wherein a threshold voltage of the pull-up transistors and the pull-down transistors limits an output swing of the output buffer.

5. A small swing output buffer comprising:
an input;
at least one pull-up device connected between the input and a voltage supply;
at least one pull-down device connected between the input and ground; and
an output, wherein the output changes in response to the input and wherein the at least one pull-up device and at least one pull-down device limit a voltage swing of the output.

6. The small swing output buffer of claim 5 wherein the at least one pull-up device and at least one pull-down device are FETs.

7. The small swing output buffer of claim 1, wherein the first p-channel FET and the second n-channel FET limit a voltage swing of the output.

8. The small swing output buffer of claim 1, wherein the p-channel FETs are changed to n-channel FETs and the n-channel FETs are changed to p-channel FETs.
